(19) United States
(12) Patent Application Publication
(10) Pub. No.: US 2024/0341057 A1
(43) Pub. Date: Oct. 10, 2024

(54) LIQUID COOLED MULTI-CHIP COLD PLATES

(71) Applicant: The Research Foundation for the State University of New York, Albany, NY (US)

(72) Inventors: Bahgat G. Sammakia, Vestal, NY (US); Yaser Hadad, Binghamton, NY (US); Mahdi Farahikia, Binghamton, NY (US); Paul Chiarot, Binghamton, NY (US)

(21) Appl. No.: 18/624,304

(22) Filed: Apr. 2, 2024

Related U.S. Application Data
(60) Provisional application No. 63/457,012, filed on Apr. 4, 2023.

(51) Int. Cl. H05K 7/20

(52) U.S. Cl. CPC H05K 7/20254; H05K 7/20272; H05K 7/20281; H05K 7/20409

(57) ABSTRACT

A liquid cooled cold plate for removing heat from an electronic apparatus. The liquid cooled cold plate includes a support base and one or more regions of high heat flux cooling structures in thermal contact with the support base. Liquid flow channels for directing a cooling liquid to flow through the cooling structures determine the flow rate and pressure of the cooling liquid. The cooling structures may include cooling posts, cooling rods, cooling cones, cooling fins and/or a complex arrangement of interconnected cooling structures such as interconnected cooling rods. These structures may be of uniform size or non-uniform size. One or more of the liquid flow channels may include a liquid throttling zone. This liquid throttling zone can be oriented horizontally or vertically relative to the support base of the liquid cooled cold plate. 3D printing as well as other manufacturing techniques may be used to produce the cold plate.

### CROSS-REFERENCE TO RELATED APPLICATIONS

This application claims the benefit of U.S. Provisional Patent Application No. 63/457,012, filed Apr. 4, 2023, the entirety of which is hereby incorporated herein by this reference.

### BACKGROUND OF THE INVENTION

### 1. Field of the Invention

The present disclosure relates to liquid cooled multi-chip cold plates, and applications thereof.

### 2. Description of the Related Art

Miniaturization of microelectronics, such as for example in a server that contains multiple microprocessors and/or graphics processors, has led to very high heat flux devices. These devices require cooling in order to operate reliably and efficiently. Traditional cooling methods such as air-based heat sinks with a large number and volume of cooling fins are inadequate to cool high-powered modern electronics. This shortcoming is even more of an issue for products like servers having multiple high heat flux devices located in close proximity to one another.

### SUMMARY OF THE INVENTION

The embodiments featured herein overcome the issues and shortcomings of traditional methods for cooling high heat flux devices. In an embodiment, a liquid cooled cold plate for removing heat from an electronic apparatus comprises a support base, a first region of cooling structures in thermal contact with the support base for removing heat from a first heat flux region of the electronic apparatus, a second region of cooling structures in thermal contact with the support base for removing heat from a second heat flux region of the electronic apparatus, and liquid flow channels for directing a cooling liquid to flow through the first region of cooling structures and the second region of cooling structures. The liquid flow channels may have either a uniform width or a non-uniform width.

In embodiments, the cooling structures may be cooling posts, cooling rods, cooling cones, cooling fins and/or a complex arrangement of interconnected cooling structures such as interconnected cooling rods. These structures may be of uniform size or non-uniform size.

In embodiments, one or more of the liquid flow channels may include a liquid throttling zone. This liquid throttling zone can be oriented horizontally or vertically relative to the support base of the liquid cooled cold plate.

In embodiments, the support base has a first thickness at the first region of cooling structures and a second thickness at the second region of cooling structures.

In embodiments, 3D printing as well as other manufacturing techniques may be used alone or in combination to produce the liquid cooled cold plates described herein.

Further features and advantages of the disclosure, as well as the structure and operation of various embodiments, are described in detail below with reference to the accompanying drawings. It is noted that the disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

FIG. 1 illustrates an exemplary traditional air-based heat sink.

FIG. 2 illustrates using traditional air-based heat sinks to cool to microelectronic devices having a uniform heat flux.

FIG. 3 illustrates using traditional air-based heat sinks to cool to microelectronic devices having a non-uniform heat flux.

FIGS. 4A-B illustrate two microelectronic devices having a non-uniform heat flux.

FIG. 5 illustrates a cold plate having uniform fins and uniform liquid flow channels.

FIG. 6 illustrates an example multi-chip cold plate according to an embodiment of the present invention.

FIG. 7 illustrates a cold plate having non-uniform fins and non-uniform liquid flow channels according to an embodiment of the present invention.

FIG. 8 illustrates an embodiment of a section of a multi-chip cold plate having non-uniform liquid flow channels according to an embodiment of the present invention.

FIG. 9 illustrates an embodiment of a section of a multi-chip cold plate having non-uniform fins according to an embodiment of the present invention.

FIG. 10 illustrates an embodiment of a cold plate having a non-uniform support base thickness according to an embodiment of the present invention.

FIG. 11 illustrates an embodiment of a liquid cooled multi-chip cold plate having a non-uniform support base thickness according to an embodiment of the present invention.

FIG. 12 illustrates an example liquid cooled multi-chip cold plate according to an embodiment of the present invention.

FIG. 13 illustrates an embodiment of a section of a multi-chip cold plate having a region of uniform cooling posts surrounded by non-uniform liquid flow channels according to an embodiment of the present invention.

FIG. 14 illustrates an embodiment of a section of a multi-chip cold plate having a region of uniform cooling rods surrounded by a region of uniform cooling posts surrounded by non-uniform liquid flow channels according to an embodiment of the present invention.

FIG. 15 illustrates an embodiment of a section of a multi-chip cold plate having a region of uniform compact cooling posts surrounded by a region of offset uniform cooling posts surrounded by non-uniform liquid flow channels according to an embodiment of the present invention.

FIG. 16 illustrates an embodiment of a section of a multi-chip cold plate having a region of uniform cooling fin surrounded by non-uniform liquid flow channels according to an embodiment of the present invention.

FIG. 17 illustrates an embodiment of a section of a multi-chip cold plate having a region of high velocity uniform cooling fin surrounded by non-uniform liquid flow channels according to an embodiment of the present invention.

FIG. 18 illustrates an embodiment of a section of a multi-chip cold plate having a region of horizontal cooling fins connected together by heat pipes surrounded by uniform liquid flow channels according to an embodiment of the present invention.

FIG. 19 illustrates an embodiment of a section of a multi-chip cold plate having a region of uniform cooling posts surrounded by non-uniform cooling fins and non-uniform liquid flow channels according to an embodiment of the present invention.

FIG. 20 illustrates an embodiment of a section of a multi-chip cold plate having a region of non-uniform cooling fins and non-uniform liquid flow channels according to an embodiment of the present invention, wherein some of the flow channels include vertical flow throttling zones.

FIG. 21 illustrates an embodiment of a section of a multi-chip cold plate having a region of non-uniform cooling fins and non-uniform liquid flow channels according to an embodiment of the present invention, wherein some of the flow channels include restrictive flow/horizontal flow throttling zones.

FIG. 22 illustrates an embodiment of a section of a multi-chip cold plate having a region of complex interconnected cooling rods surrounded by non-uniform liquid flow channels according to an embodiment of the present invention.

FIG. 23 illustrates an embodiment of a section of a multi-chip cold plate having a region of uniform cooling posts surrounded by a region of converging and diverging liquid flow channels according to an embodiment of the present invention.

FIG. 24 illustrates an embodiment of a section of a multi-chip cold plate having a region of uniform cooling cones according to an embodiment of the present invention.

FIG. 25 illustrates an embodiment of a section of a multi-chip cold plate having a region of different heighted cooling posts according to an embodiment of the present invention.

FIG. 26 illustrates an example liquid cooled multi-chip cold plate according to an embodiment of the present invention.

FIG. 27 illustrates an example liquid cooled multi-chip cold plate according to an embodiment of the present invention.

FIG. 28 illustrates an example liquid cooled multi-chip cold plate according to an embodiment of the present invention.

FIG. 29 illustrates an example liquid cooled cold plate cooling system according to an embodiment of the present invention.

FIG. 30 illustrates an example liquid cooled cold plate cooling system according to an embodiment of the present invention.

FIG. 31 illustrates an example of a liquid flow nozzle according to an embodiment of the present invention.

### DETAILED DESCRIPTION

Embodiments will be described below in more detail with reference to the accompanying drawings. The following detailed descriptions are provided to assist the reader in gaining a comprehensive understanding of the methods, apparatuses, and/or systems described herein as well as modifications thereof. Accordingly, various modifications and equivalents of the methods, apparatuses, and/or systems described herein will be apparent to those of ordinary skill in the art. Descriptions of well-known functions and constructions may be omitted for increased clarity and conciseness.

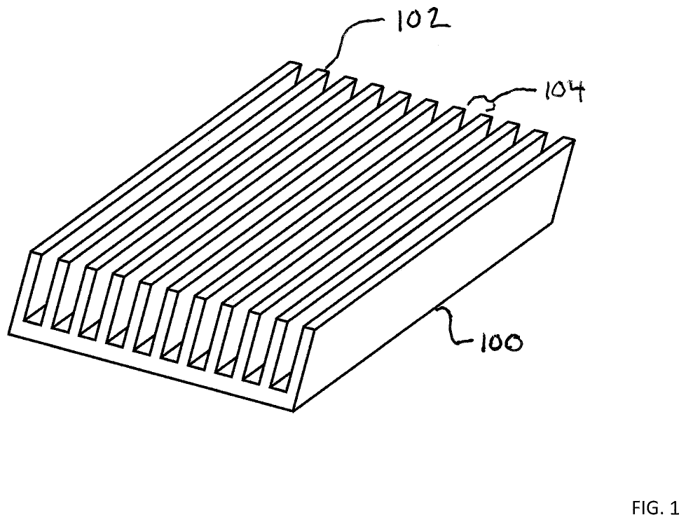

FIG. 1 illustrates an example of a traditional air-based heat sink 100. Heat sink 100 includes multiple cooling fins 102 and air gaps 104 between the cooling fins 102. The cooling fins 102 and the air gaps 104 between cooling fins 102 are uniform.

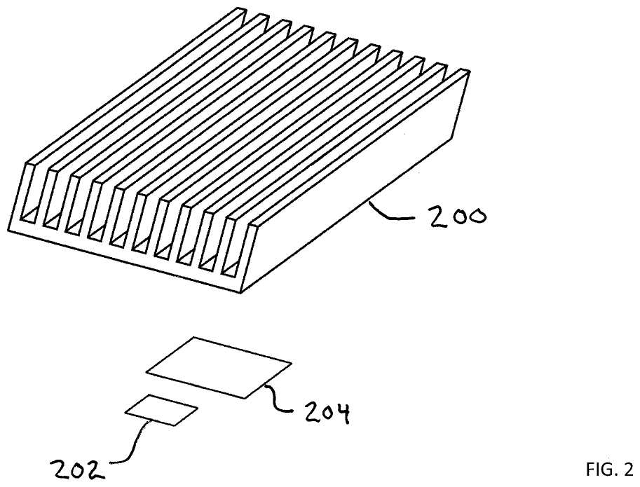

FIG. 2 illustrates two micro-processing units 202 and 204, which can form part of a typical electronic apparatus such as for example a computer server. Microprocessor 202 might represent for example a computer processing unit or CPU and microprocessor 204 might represent a graphics processing unit or GPU. Traditionally, these micro-processing units would be cooled using a large heat sink 200. This traditional cooling method is quickly becoming obsolete because miniaturization of current microprocessors allows for the placement of these microprocessor closer together than before, and due to their miniaturization, they run hotter and require more cooling. To cool these hotter running microprocessors, larger traditional heat sinks are required, but they cannot be used when the smaller microprocessors are placed closer together and in general they cannot provide the required cooling.

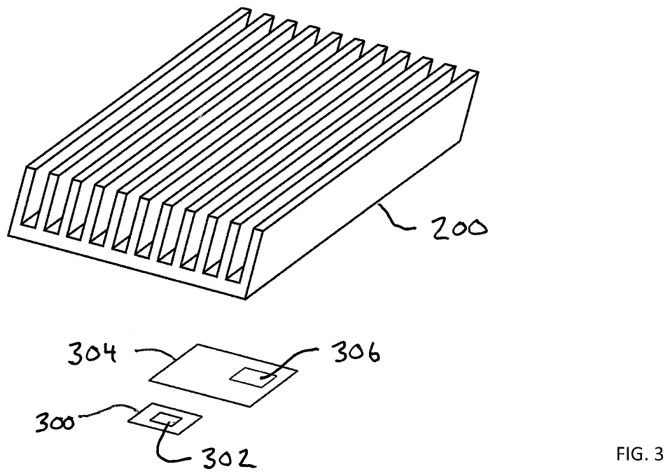

FIG. 3 illustrates two micro-processing units 300 and 304, which can form part of a typical electronic apparatus such as for example a computer server. Microprocessor 300 includes a high heat flux region 302, and microprocessor 304 includes a high heat flux region 306. Attempting to cool these two microprocessors with heat sink 200 has the same issue as described above with reference to FIG. 2. In addition, the cooling surface of heat sink 200 is not well suited to remove heat from the high heat flux regions 302 and 306, so the microprocessors 300 and 304 will not be properly or optimally cooled, and as a result will have a shortened lifetime and run less efficiently.

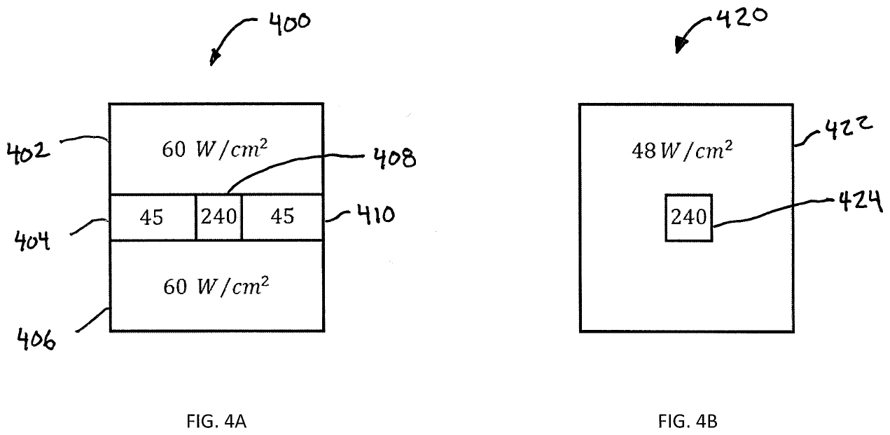

FIGS. 4A-B illustrate two microelectronic devices 400 and 420 that having non-uniform heat fluxes. As shown in FIG. 4A, microelectronic device 400 has five regions in which each region has its own heat flux rate. Region 402 has a heat flux of 60 W/cm². Region 404 has a heat flux of 45 W/cm². Region 406 has a heat flux of 60 W/cm². Region 408 has a heat flux of 240 W/cm². Region 410 has a heat flux of 45 W/cm². Similarly, as shown in FIG. 4B, microelectronic device 420 has two regions in which each region has its own heat flux rate. Region 422 has a heat flux of 48 W/cm². Region 424 has a heat flux of 240 W/cm². Traditional cooling methods do not work well for microelectronic devices such as microelectronic devices 400 and 420.

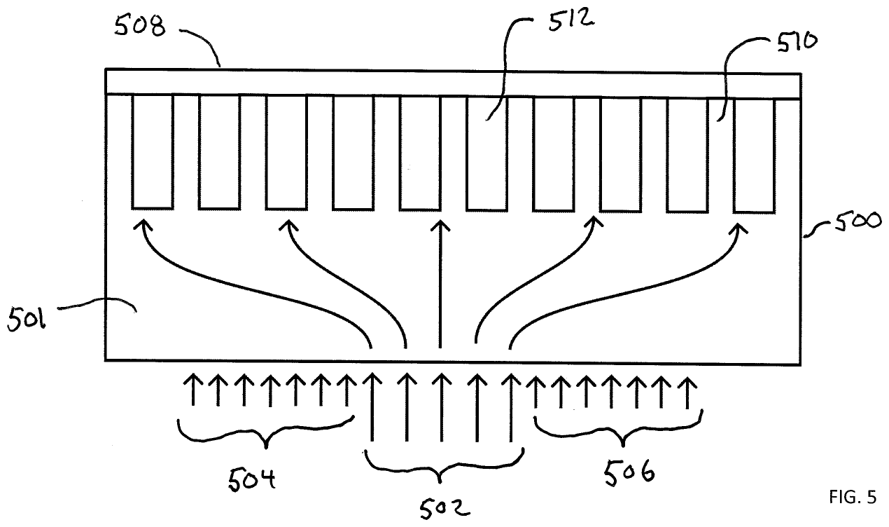

FIG. 5 illustrates a cold plate 500 having uniform cooling fins 510 and uniform liquid flow channels 512 located between the cooling fins 510. A lid or top plate 508 ensures that a liquid flowing within the liquid flow channels 512 remains within the liquid flow channels 512.

As shown in FIG. 5, heat sink 500 is being used to extract heat from a microelectronic devise (not shown) that has three heat flux regions 502, 504, and 506. The region 502 has a higher heat flux than regions 504 and 506. In order to optimally utilize the cooling fins 510 and liquid flow channels 512, a large/thick support base is needed to allow heat from high heat flux region 502 to spread out and make its way to fins not directly above high heat flux region 502. This thick support base is undesirable in many applications because it adds weigh and cost to the electronic apparatus in which it is used.

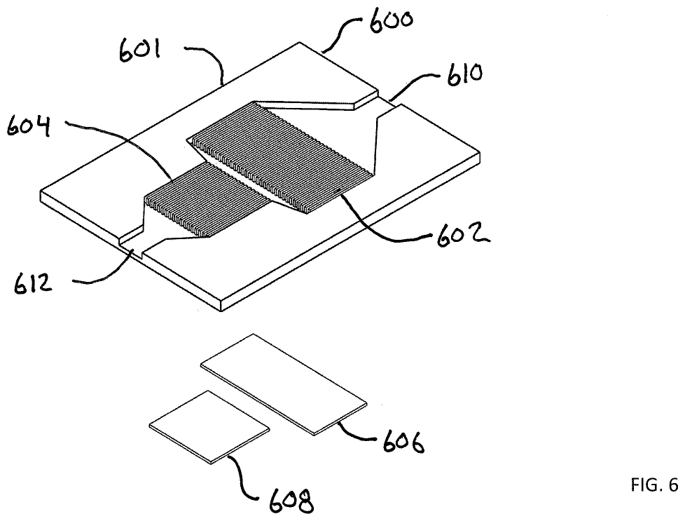

FIG. 6 illustrates an example liquid cooled multi-chip cold plate 600 according to an embodiment of the present invention. Cold plate 600 is used to cool microprocessor or device 606 and microprocessor or device 608. As shown in FIG. 6, cold plate 600 has a first region of cooling structures 602 and a second region of cooling structures 604. Region 603 between cooling structures 602 and 604 directs the cooling frow from cooling structure 602 to cooling structure 604. The cooling structures in region 602 and region 604 are in thermal contact with support base 601 of cold plate 600. The cooling structures in region 602 are optimized to cool device 606, and the cooling structures in region 604 are optimized to cool device 608. A cooling liquid flows into cold plate 600 via the diverging liquid flow channel 610, flows through the cooling structures in regions 602 and 604, and then exits cold plate 600 via converging liquid flow channel 612.

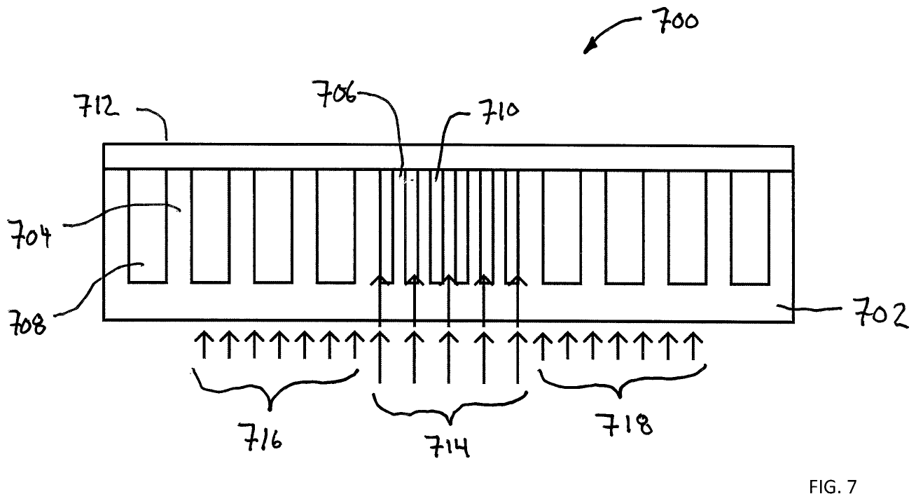

FIG. 7 illustrates a cold plate 700 having non-uniform fins and non-uniform liquid flow channels according to an embodiment of the present invention. As shown in FIG. 7, heat sink 700 has a support base 702, cooling fins 704 of a first width, cooling fins 706 of a second width, and a lid or top plate 712. Cooling fins 704 are wider that cooling fins 706, and cooling fins 704 are spaced further apart than cooling fins 706. The spaces between cooling fins 704 for a first group of liquid flow channels 708, which are wider than a second group of liquid flow channels 710 that are formed by cooling fins 706. The cooling fins 706 and liquid flow channels 710 are directly above a region of high heat flux 714. The cooling fins 704 and liquid flow channels 708 are above regions of lower heat flux 716 and 718. Because of the design of heat sink 700, support base 702 can be thinker and less expensive that that of a traditional heat sink. By controlling the pressure for example of the liquid flowing through the various liquid flow channels, the volume of liquid flowing through each liquid flow channel and the heat removed by the liquid can be precisely controlled.

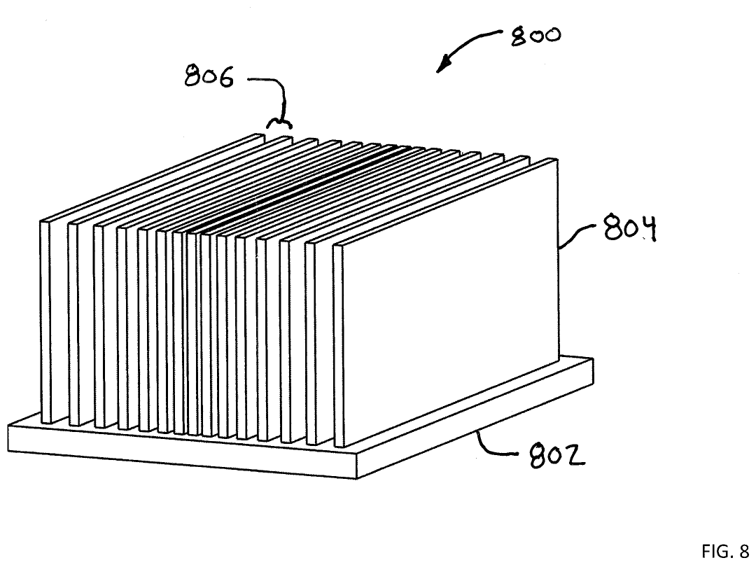

FIG. 8 illustrates an embodiment of a section 800 of a multi-chip cold plate, such as for example cold plate 600, having non-uniform liquid flow channels 806 according to an embodiment of the present invention. As shown in FIG. 8, section 800 of the cold plate includes a number of cooling fins 804 having a uniform thickness. The cooling fins 804 are in thermal contact with support base 802. The spacing of the cooling fins 804, however, is non-uniform, and so the liquid flow channels 806 between the cooling fins 804 are not uniform. The spacing of the cooling fins 804 is set so as to get a desired heat removal rate as would be understood by persons skilled in the relevant arts given the description given herein.

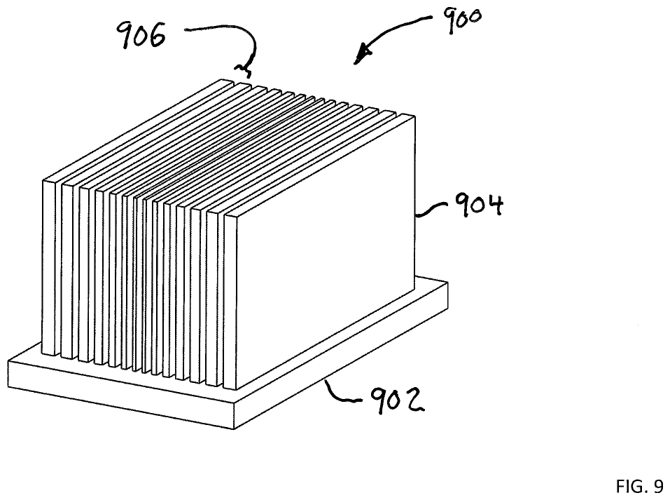

FIG. 9 illustrates an embodiment of a section 900 of a multi-chip cold plate having non-uniform fins 904 according to an embodiment of the present invention. As shown in FIG. 9, section 900 of the cold plate includes a number of cooling fins 904 having a non-uniform thickness. The cooling fins 904 are in thermal contact with support base 902. The thicknesses of the cooling fins 904 are adjusted to get a desired heat removal rate from each of the fins 904.

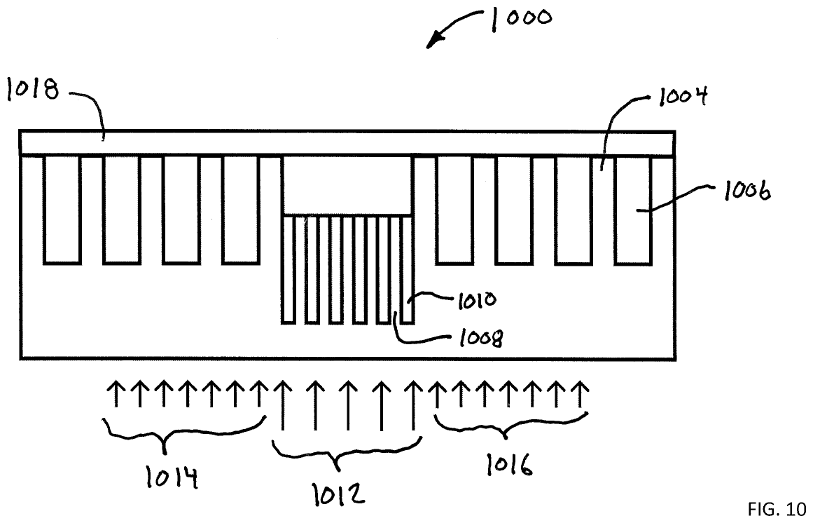

FIG. 10 illustrates an embodiment of a liquid cooled heat sink 1000 having a support base 1002 of non-uniform thickness according to an embodiment of the present invention. As shown in FIG. 10, heat sink 1000 has a base 1002, fins 1004, fins 1008, and a lid or top plate 1018. The fins 1004 form liquid flow channels 1006, and the fins 1008 form liquid flow channels 1010. The fins 1008 are thinner than fins 1004, and they are spaced closer together than fins 1004, which provides more surface area to contact a cooling liquid. The fins 1008 and the liquid cooling channels 1010 are directly above a region of high het flux 1012. The support base 1002 in this region is thinner to facilitate the transfer of heat to cooling fins 1008 and cooling channels 1010. The support base 1002 is thicker in other regions to facilitate heat spreading. The support base 1002 is thinner under fins 1008 than under fins 1004. The fins 1004 are above regions of heat flux 1014 and 1016. The lid 1018 serves to keep the cooling liquid flowing through liquid flow channels 1006 and 1010 within the liquid flow channels.

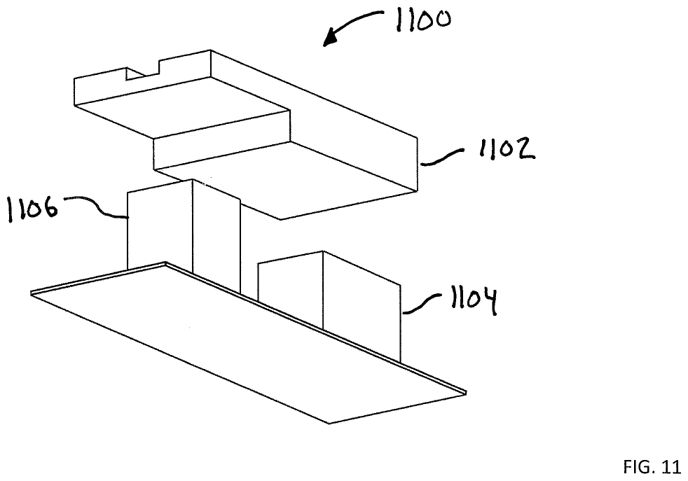

FIG. 11 illustrates an embodiment of a liquid cooled multi-chip cold plate 1100 having a non-uniform support base thickness according to an embodiment of the present invention. A support base 1102 of cold plate 1100 is in thermal contact with two devices 1004 and 1006. As shown in FIG. 1100, the thickness of support base 1102 in the region of device 1104 is thicker than that in the region of device 1106 to match the heigh of the devices. In embodiments, the thickness of the support base 1002 is adjusted based on the heat fluxes of the chips to be cooled as would be understood by persons skilled in the relevant art(s) given the description provided herein.

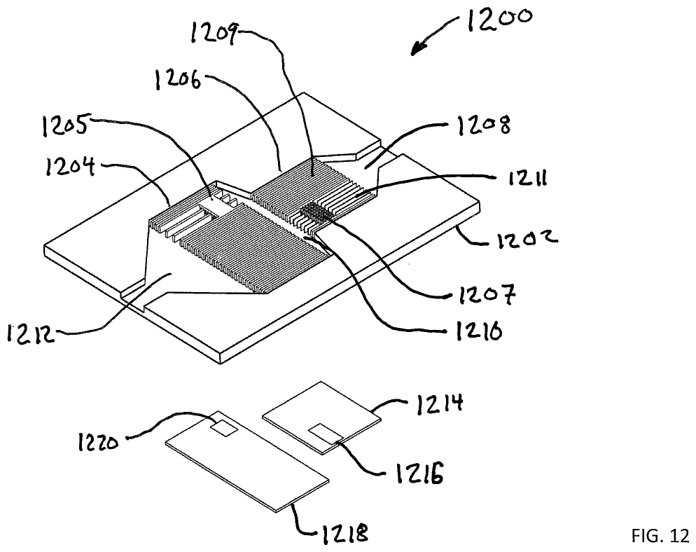

FIG. 12 illustrates an example liquid cooled multi-chip cold plate 1200 according to an embodiment of the present invention. Cold plate 12200 is used to cool a chip 1214 and a chip 1218. Chip 1214 has a region of high heat flux 1216, and chip 1218 has a region of high heat flux 1220.

In operation, a cooling liquid (not shown) enters cold plate 1200 at a diverging liquid flow channel 1208 and enters a first region of cooling structures 1206. This first region of cooling structures has cooling fins 1209 that are closely spaced together and cooling fins 1211 that are spaced further apart than fins 1209. It also has a plurality of cooling posts 1207. When the cooling liquid exists flow channel 1208 it enters the liquid flow channels formed by cooling fins 1209 and the liquid flow channels formed by cooling fins 1211. The liquid flowing within the cooling fins 1211 also flows through the cooling posts 1207, as shown in FIG. 12. The cooling posts are directly above the region of high heat flux 1216 of chip 1214 to provide additional cooling for high heat flux region 1216.

When the cooling liquid exist the first region of cooling structures 1206, it diverges and flows through a second region of cooling structures 1204. Region 1210 directs the flow from cooling structures 1206 to cooling structures 1204. In addition to cooling fins of non-uniform thicknesses, and liquid flow channels of non-uniform widths, the second region of cooling structures 1204 has a liquid throttling zone 1205, which is vertical to support plate 1202. The liquid throttling zone 1205 is directly above region of high heat flux 1220 of chip 1218 and provides additional cooling for region of high heat flux 1220.

When the cooling liquid exits the second region of cooling structures 1204, it enters a converging liquid flow channel 1212 and then exits cold plate 1200. The cooling structures are designed and sized to provide optimal cooling of chips 1214 and 1218.

In embodiments, the cooling structures of cold plate 1200 are formed by 3D printing some or all of the cooling structures on a machined support base 1202.

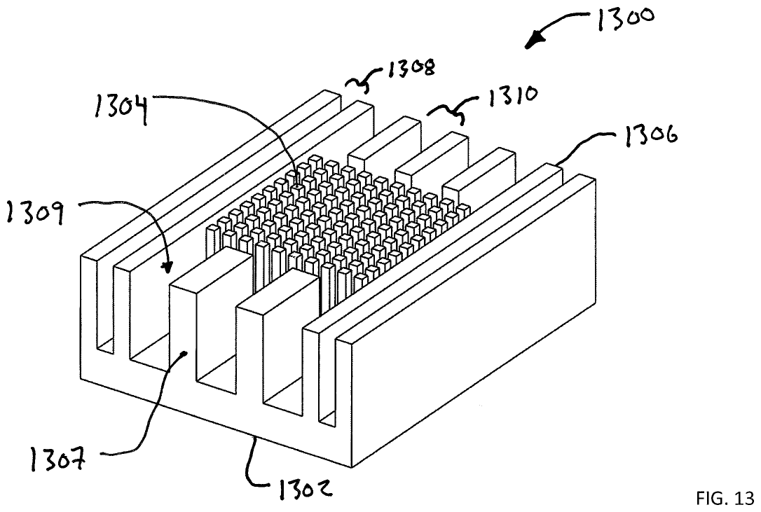

FIG. 13 illustrates an embodiment of a cold plate section 1300 having a region of uniform cooling posts 1304 surrounded by non-uniform liquid flow channels according to an embodiment of the present invention. As shown in FIG. 13, cooling posts 1304 are in thermal contact with a support base 1302. Cold plate section 1300 also includes cooling fins 1306 and cooling fins 1307, which are in thermal contact with support base 1302. Cooling fins 1307 are thicker than cooling fins 1306. The cooling fins 1306 and 1307 form liquid flow channels 1308, 1309, and 1310, each of which has a different width. In embodiments, cold plate section 1300 represents a region of cooling structures of a cold plate similar, for example, to region of cooling structures 1206 illustrated in FIG. 12.

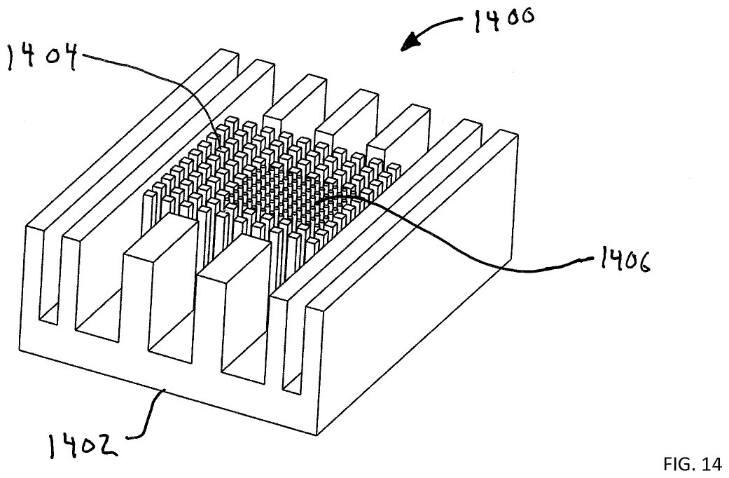

FIG. 14 illustrates an embodiment of a cold plate section 1400 having a region of uniform cooling rods 1406 surrounded by a region of uniform cooling posts 1404 surrounded by non-uniform liquid flow channels according to an embodiment of the present invention. Cold plate section 1400 is similar to cold plate section 1300 except that a portion of the cooling posts has been replaced cooling rods. The cooling rods 1406 have a greater surface area in contact with a cooling liquid flowing through them than do the cooling posts 1404, and thus can transfer more heat to the cooling liquid. Both the cooling posts 1404 and the cooling rods 1406 are in thermal contact with the support base 1402.

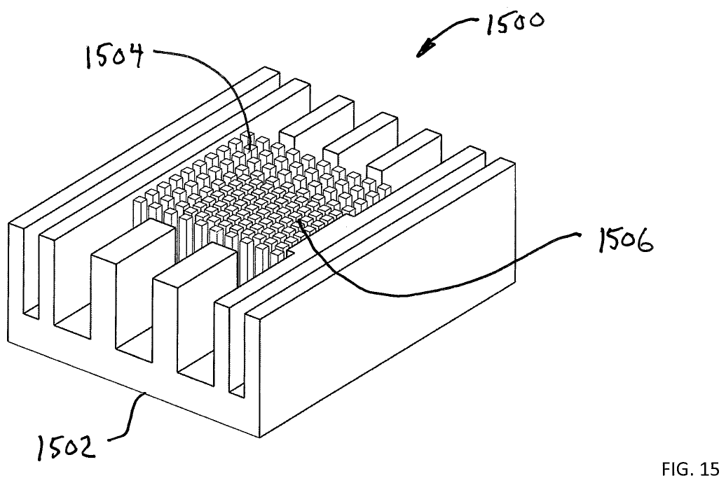

FIG. 15 illustrates an embodiment of a cold plate section 1500 having a region of uniform compact cooling posts 1506 surrounded by a region of offset uniform cooling posts 1504 surrounded by non-uniform liquid flow channels according to an embodiment of the present invention. Cold plate section 1500 is similar to cold plate section 1400 except that a portion of the cooling posts has been replaced by smaller, offset cooling posts 1506. The cooling posts 1506 have a greater surface area in contact with a cooling liquid flowing through them than do the cooling posts 1504, and thus can transfer more heat to the cooling liquid. The offset between cooling posts 1504 and 1506 causes turbulent flow of a cooling liquid flowing through the cooling posts. Both the cooling posts 1504 and the cooling rods 1506 are in thermal contact with the support base 1502.

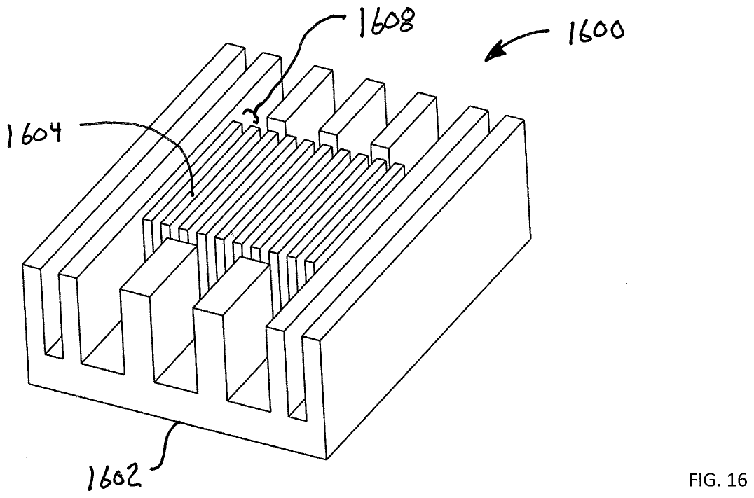

FIG. 16 illustrates an embodiment of a cold plate section 1600 having a region of uniform cooling fin 1604 surrounded by non-uniform liquid flow channels according to an embodiment of the present invention. Cold plate section 1600 is similar to cold plate section 1300 except that the region of cooling posts 1304 has been replaced by a region of cooling fins 1604. The cooling fins 1604 form uniform liquid flow channels 1608. The cooling fins 1604 are in thermal contact with support base 1602.

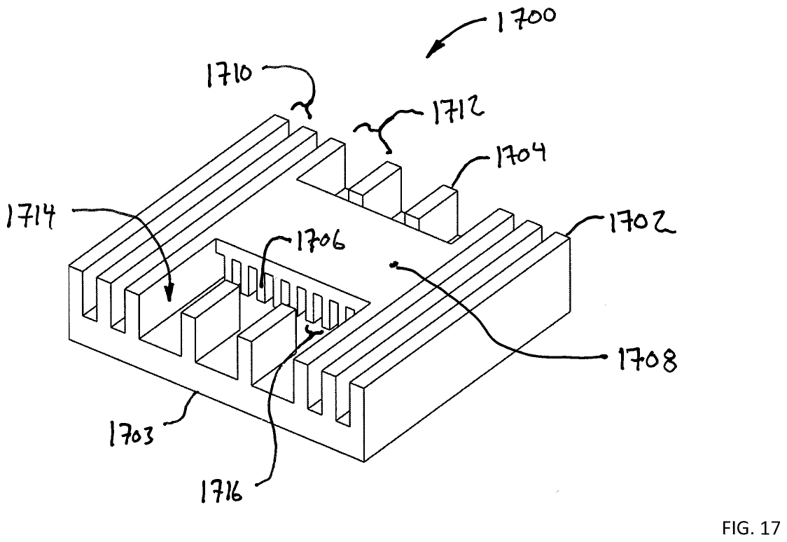

FIG. 17 illustrates an embodiment of a cold plate section 1700 having a region of high velocity uniform cooling fin 1706 surrounded by non-uniform liquid flow channels according to an embodiment of the present invention. As shown in FIG. 17, cold plate section 1700 includes cooling fins 1702, 1704, and 1706. Cooling fins 1706 are the thinnest cooling fins, and they are capped by a horizontal plate 1708. Between these different cooling fins, various liquid flow channels are formed. These liquid flow channels are liquid flow channel 1710, liquid flow channel 1712, liquid flow channel 1714, and liquid flow channel 1716. The cooling fins 1706 and the horizontal plate 1708 form a horizontal liquid flow nozzle that accelerates a cooling liquid flowing within liquid flow channels 1716. All of the cooling fins of cold plate section 1700 are in thermal contact with support base 1703.

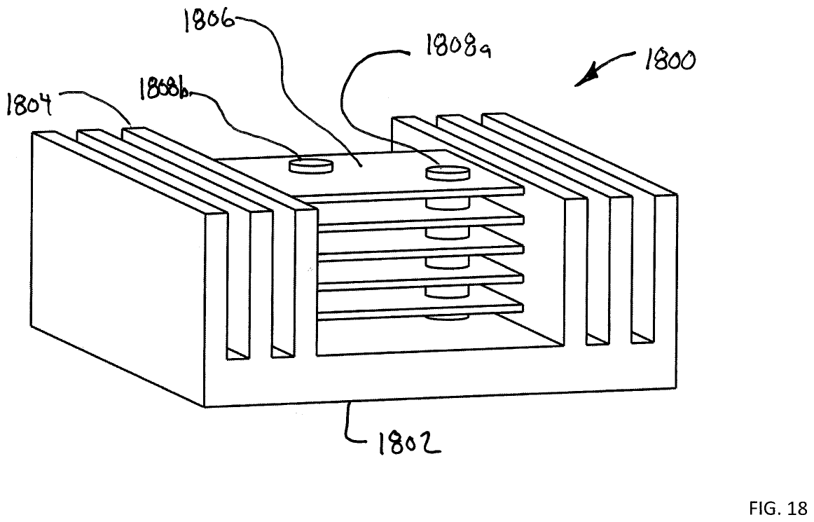

FIG. 18 illustrates an embodiment of a cold plate section 1800 having a region of horizontal cooling fins 1806 connected together by heat pipes 1808a and 1808b surrounded by uniform liquid flow channels according to an embodiment of the present invention. As shown in FIG. 18, cold plate section 1800 includes both vertical cooling fins 1804 and horizontal cooling fins 1806. The cooling fins 1804 are directly in thermal contact with support base 1802, while the horizontal cooling fins 1806 are in thermal contact with support base 1802 via heat pipes 1808a and 1808b. The cooling properties of cold plate section 1800 can be adjusted as desired by adjusting the dimensions of the cooling structures shown.

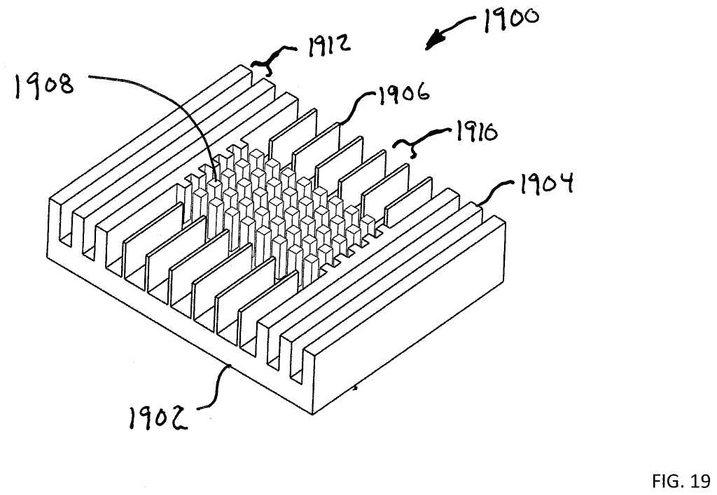

FIG. 19 illustrates an embodiment of a cold plate section 1900 having a region of uniform cooling posts 1908 surrounded by non-uniform cooling fins and non-uniform liquid flow channels according to an embodiment of the present invention. Cold plate section 1900 includes cooling fins 1904 and 1906. The cooling fins 1904 form liquid flow channels 1912, and the cooling fins 1906 form liquid flow channels 1910. The liquid flow channels 1910 direct a cooling liquid to flow through the region of cooling posts 1908. The cooling fins and cooling rods of cold plate section 1900 are in thermal contact with support base 1902. In embodiments, the region of cooling posts 1908 is directly above a region of high heat flux of a chip or microelectronic device.

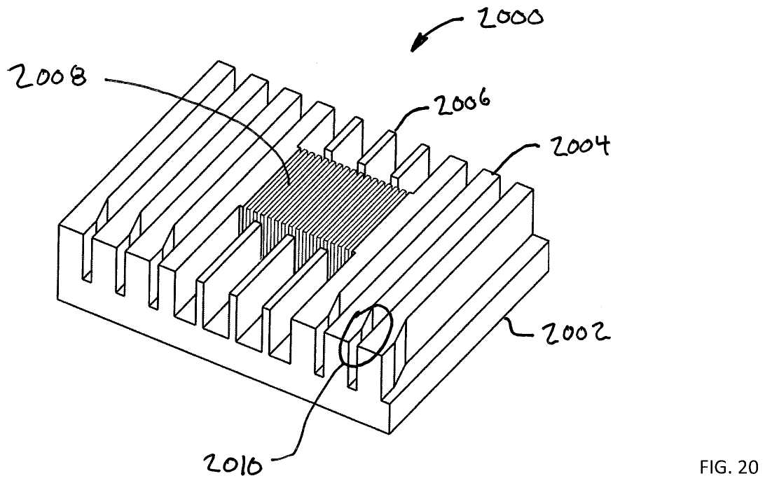

FIG. 20 illustrates an embodiment of a cold plate section 2000 having a region of non-uniform cooling fins and non-uniform liquid flow channels according to an embodiment of the present invention, wherein some of the flow channels include vertical flow throttling zones 2010. As shown in FIG. 20, cold plate section 2000 has three sizes of cooling fins 2004, 2006, and 2008. Cooling fins 2008 are the thinnest cooling fins. One end of cooling fins 2004 is thicker than its first end, and this thicker end forms a vertical flow throttling zone 2010 as shown in FIG. 20. Vertical flow throttling zone 2010 accelerates the flow of a cooling liquid passing through vertical flow throttling zone 2010. In embodiments, the region of cooling fins 2008 is directly above a region of high heat flux of a chip or microelectronic device.

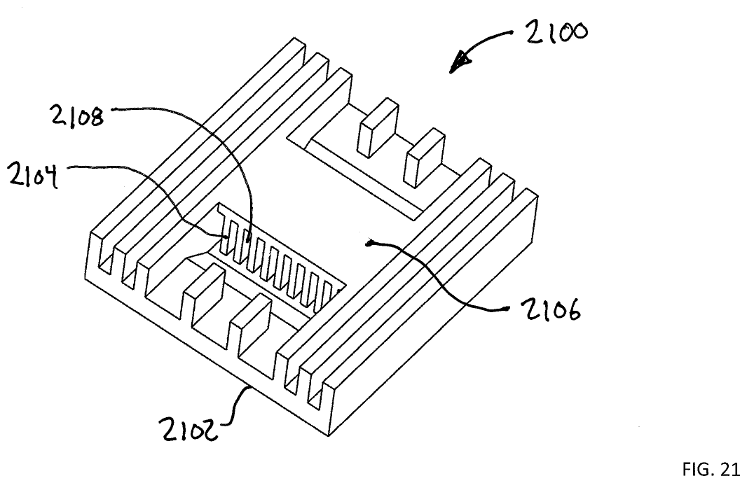

FIG. 21 illustrates an embodiment of a cold plate section 2100 having a region of non-uniform cooling fins and non-uniform liquid flow channels according to an embodiment of the present invention. As shown in FIG. 21, cold plate section 2100 includes cooling fins 2104 having a top plate 2106. The cooling fins 2104 and top plate 2106 form liquid flow channels 2108. Together, these structures form a restrictive flow/horizontal flow throttling zone. The cooling fins 2104 are in thermal contact with support base 2102, as are the other cooling fins of cold plate section 2100. As can be seen in FIG. 21, the support base 2102 is thinner in the region of cooling fins 2104 than in the regions of the other cooling fins of cold plate section 2100. In embodiments, the region of cooling fins 2104 is directly above a region of high heat flux of a chip or microelectronic device.

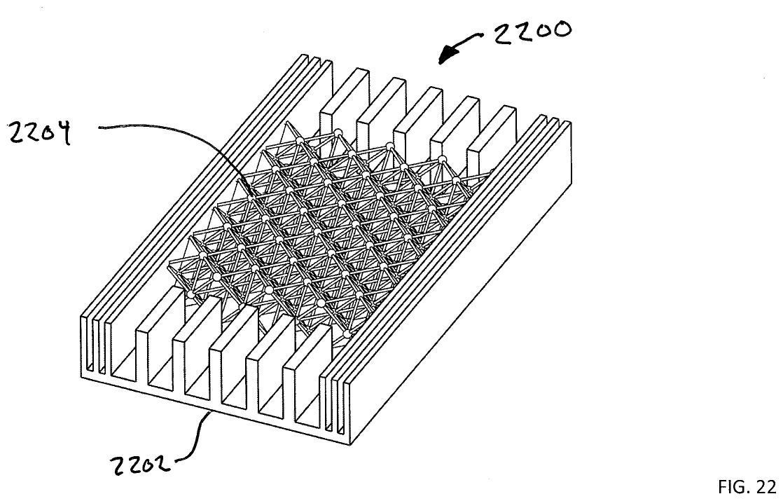

FIG. 22 illustrates an embodiment of a cold plate section 2200 having a region of complex interconnected cooling rods 2204 surrounded by non-uniform liquid flow channels according to an embodiment of the present invention. The complex interconnected cooling rods 2204 are in thermal contact with support base 2202. The complex interconnected cooling rods 2204 provide a large cooling surface and cause turbulence and mixing of a cooling liquid flowing through the region of complex interconnected cooling rods 2204. In embodiments, the complex interconnected cooling rods 2204 are produced by 3D printing. Other complex cooling structures produced by 3D print are also possible and can be used to cool a high heat flux region of a chip or microelectronic device as described herein.

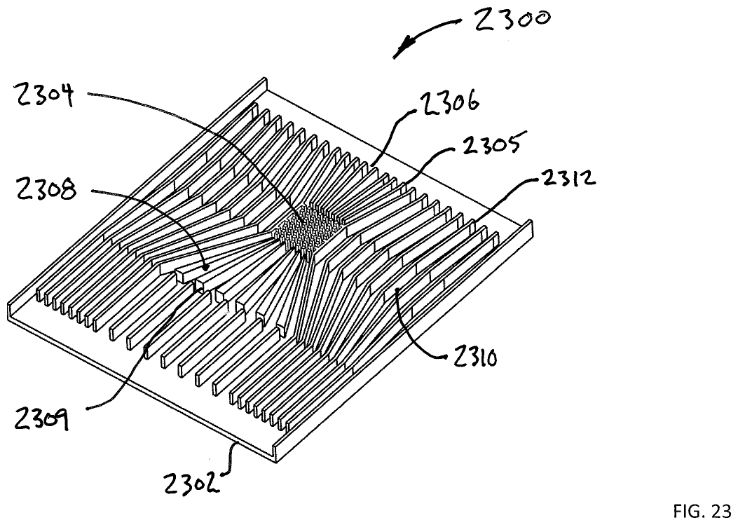

FIG. 23 illustrates an embodiment of a cold plate section 2300 having a region of offset, uniform cooling posts 2304 surrounded by a region of converging and diverging liquid flow channels 2306, 2308 and 2310 according to an embodiment of the present invention. In embodiments, the offset cooling posts 2304 are directly above a region of high heat flux of a chip or microelectronic device. The offset cooling posts 2304 cause turbulence and mixing of a cooling liquid flowing through cooling posts 2304. Cooling fins 2305 form converging liquid flow channels 2306 that direct a cooling liquid to flow through cooling posts 2304. Cooling fins 2309 form diverging liquid flow channels 2308 within which the cooling liquid flows after leaving the region of cooling posts 2304. To the sides of the region of cooling posts 2304 are cooling fins 2312 that form liquid flow channels 2310. These cooling structures are selected and sized to optimally cool a chip or microelectronic device in thermal contact with the underside of support base 2302. All of the cooling structures shown in FIG. 23 on the top side of cold plate section 2300 are also in thermal contact with support base 2302.

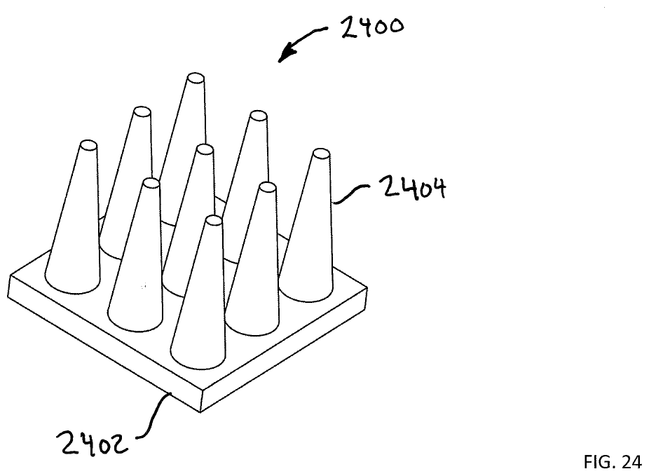

FIG. 24 illustrates an embodiment of a cold plate section 2400 having a region of uniform cooling cones 2404 according to an embodiment of the present invention. The cooling cones 2404 are tapered and are in thermal contact with support base 2402. In embodiments, the cooling cones 2404 are used, for example, in places similar to that shown herein for cooling posts and cooling rods.

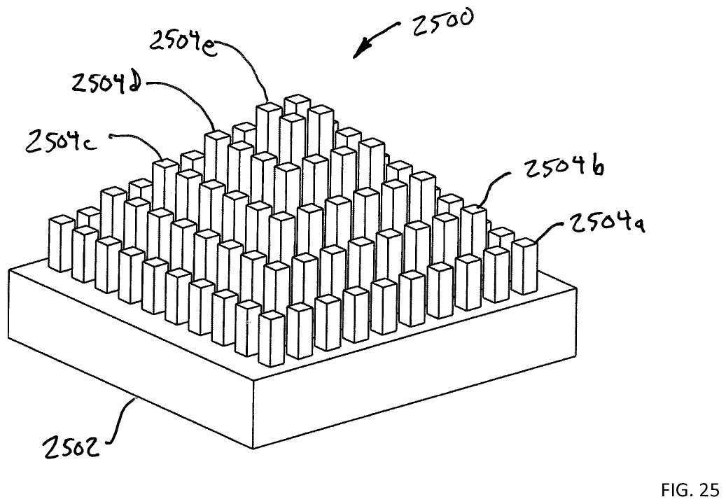

FIG. 25 illustrates an embodiment of a cold plate section 2500 having a region of different heighted cooling posts 2504a-e according to an embodiment of the present invention. All of the cooling rods 2504a-e are in thermal contact with support base 2502. In embodiments, the cooling rods 2504a-e are formed using 3D printing.

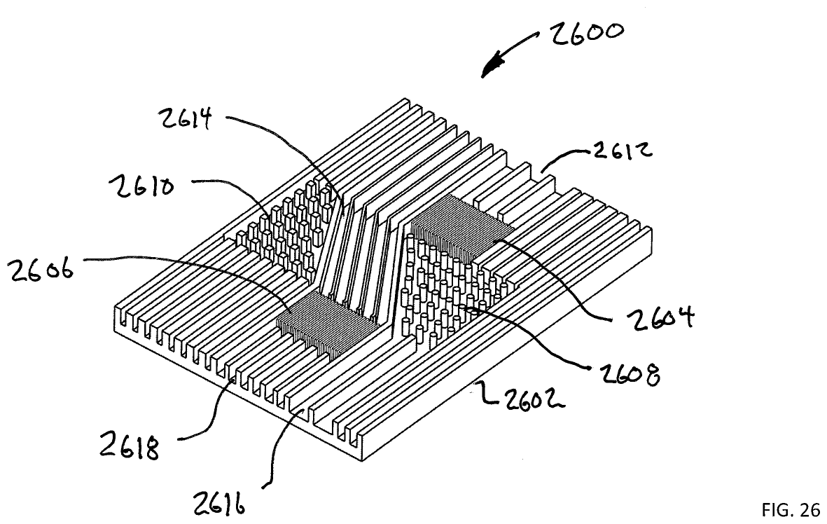

FIG. 26 illustrates an example liquid cooled multi-chip cold plate 2600 according to an embodiment of the present invention. Cold plate 2600 includes a first region of cooling fins 2604 and a second region of cooling fins 2606. It also includes a region of cooling rods 2608 and a region of cooling posts 2610. The regions of cooling fins 2604 and 2606 are intended to be directly above regions of high heat flux of two different chips such as for example two microprocessors. Different sized cooling fins of cold plate 2600 form liquid flow cooling channels of different sizes, such as liquid flow channels 2612, 2614, 2616, and 2618. Liquid flow channels 2612 direct cooling liquid to flow through the region of cooling fins 2604, and the liquid flow channels 2616 direct the flow of the cooling liquid after it exits the region of cooling fins 2604. Liquid flow channels 2614 direct cooling liquid to flow through the region of cooling fins 2606, and the liquid flow channels 2618 direct the flow of the cooling liquid after it exits the region of cooling fins 2606. All of the cooling structures shown in FIG. 26 are in thermal contact with support base 2602. In embodiments, the cooling structures of cold plate 2600 may be formed using 3D printing.

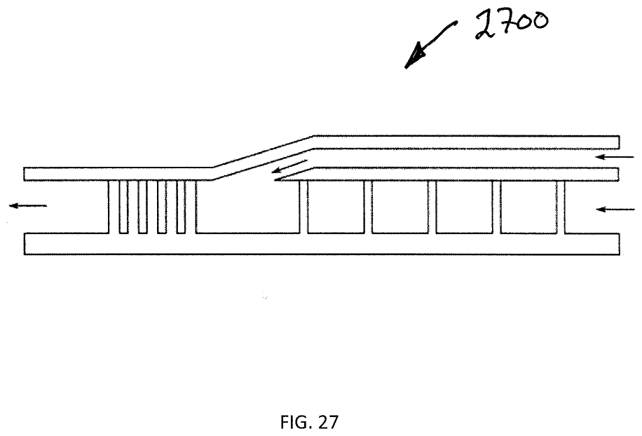

FIG. 27 illustrates an example liquid cooled multi-chip cold plate section 2700 according to an embodiment of the present invention. As shown in FIG. 27, a cold plate according to the present invention can have vertical liquid flow channels as well as horizontal flow channels. The vertical liquid flow channels are formed using cooling fins or plates oriented horizontally to the support base of the cold plate.

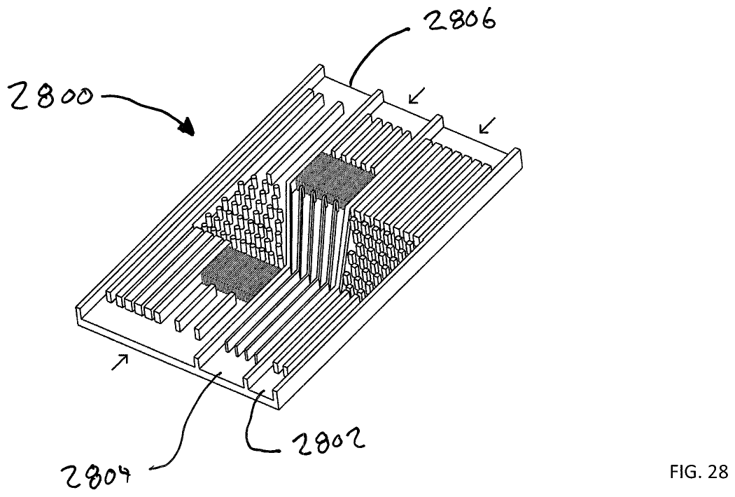

FIG. 28 illustrates an example liquid cooled multi-chip cold plate 2800 according to an embodiment of the present invention. As Shown in FIG. 28, the cooling liquid flowing through a cold plate according to the present invention is not limited to flowing in just one direction. In cold plate 2800, there are three primary liquid flow channels 2802, 2804, and 2806. The cooling liquid flows in the opposite direction in liquid flow channel 2806 as it does in liquid flow channels 2802 and 2804. In embodiments, the cooling liquid flowing out of one or more of the liquid flow channels can flow back into another liquid flow channel. In an embodiment, different cooling liquids are used in different flow channels. In embodiments, some channels may have two-phase liquid flow while other channels have one-phase liquid flow.

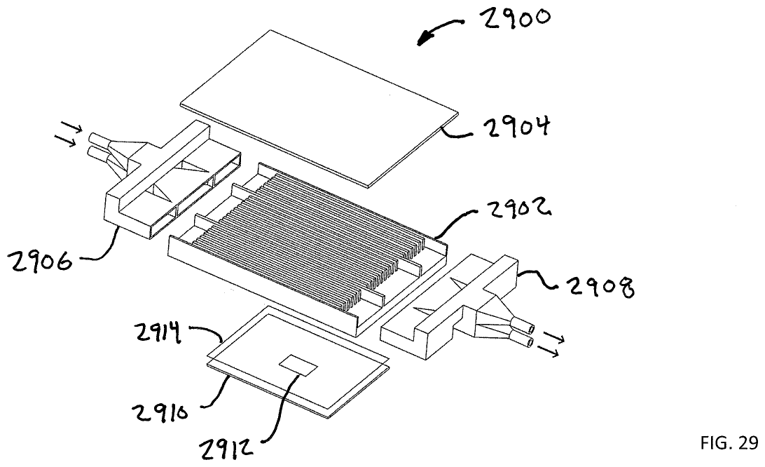

FIG. 29 illustrates an example liquid cooled cold plate cooling system 2900 according to an embodiment of the present invention. Cooling system 2900 includes a cold plate 2902, a lid or top plate 2904, a cooling liquid flow nozzle 2906, and a cooling liquid flow nozzle 2908. A microelectronic device 2910 having a region of high heat flux 2912 is in thermal contact with the underside of support base of cold plate 2902. In embodiments, a thermally conducting tape such as thermal tape 2914 can be used to hold microelectronic device 2910 in thermal contact with cold plate 2902. Liquid flow nozzle 2906 direct cooling liquid through the cooling structures of cold plate 2902. The cooling liquid exits cold plate 2902 via liquid flow nozzle 2908. As shown in FIG. 29, liquid flow nozzles 2906 and 2908 have two flow paths for the cooling liquid to enter and exit the liquid flow nozzles. In embodiments, the two flow paths can be used for cooling liquids of different temperatures and/or different pressures.

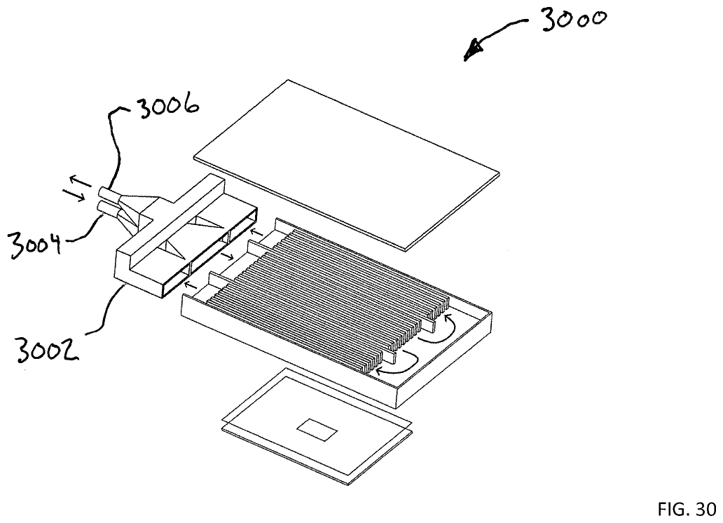

FIG. 30 illustrates an example liquid cooled cold plate cooling system 3000 according to an embodiment of the present invention. As shown in FIG. 30, liquid cooled cold plate cooling system 3000 includes a single liquid flow nozzle 3002 rather than two liquid flow nozzles as is the case with liquid cooled cold plate cooling system 2900. As shown, the cooling liquid enters inlet 3004 of liquid flow nozzle 3002 and exits from outlet 3006.

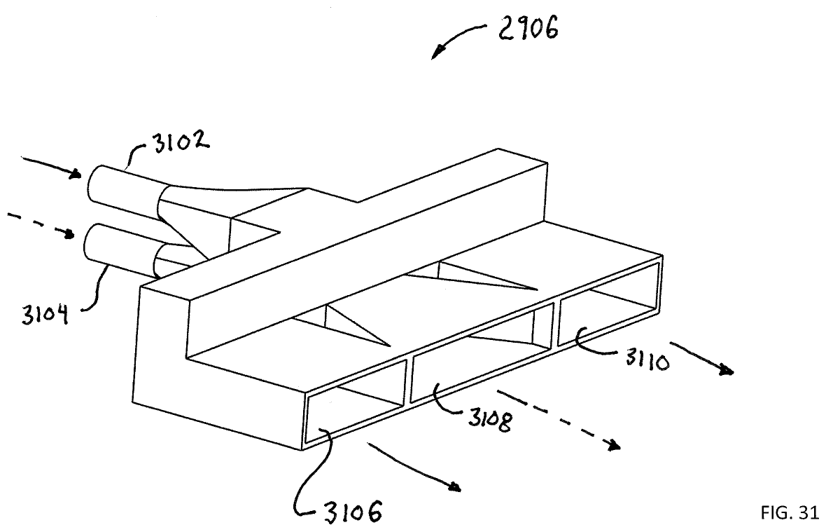

FIG. 31 further illustrates liquid flow nozzle 2906 according to an embodiment of the present invention. As shown in FIG. 31, liquid flow nozzle 2906 has two cooling liquid inlets 3102 and 3104, and it has three cooling liquid outlets 3106, 3108, and 3110. In an embodiment, the cooling liquid that enters inlet 3102 flows out of outlets 3106 and 3110. The cooling liquid that enters inlet 3104 flows out of outlet 3108. Other liquid flow nozzles according to the present invention have different flow patterns than that shown in FIG. 31.

More details related to designing liquid cooled cold plates, cooling structures, and cooling systems are presenting in the following papers, each of which in incorporated herein by reference: (1) “Experimental Characterization of Cold Plates used in Cooling Multi Chip Server Modules (MCM),” 2018 17th IEEE Intersociety Conference on Thermal and Thermomechanical Phenomena in Electronic Systems (ITherm), San Diego, CA, USA, 2018, pp. 664-672; (2) “Characterization of Liquid Cooled Cold Plates for a Multi Chip Module (MCM) and their Impact on Data Center Chiller Operation,” 2019 IEEE 17th International Conference on Industrial Informatics (INDIN), Helsinki, Finland, 2019, pp. 1419-1424; and (3) Minimizing the Effects of On-Chip Hotspots Using Multi-Objective Optimization of Flow Distribution in Water-Cooled parallel Microchannel Heatsinks,” Journal of Electronic Packaging, Vol. 143, June 2021.

Those skilled in the relevant art(s) will readily appreciate that various adaptations and modifications of the exemplary embodiments described above can be achieved without departing from the scope and spirit of the present disclosure. Therefore, it is to be understood that, within the scope of the appended claims, the teachings of the disclosure may be practiced other than as specifically described herein.

What is claimed is:

1. A liquid cooled cold plate for removing heat from an electronic apparatus, comprising:
a support base;
a first region of cooling structures in thermal contact with the support base for removing heat from a first heat flux region of the electronic apparatus;
a second region of cooling structures in thermal contact with the support base for removing heat from a second heat flux region of the electronic apparatus; and
liquid flow channels for directing a cooling liquid to flow through the first region of cooling structures and the second region of cooling structures,
wherein the liquid flow channels have a non-uniform width.

2. The liquid cooled cold plate of claim 1, wherein the first region of cooling structures comprises one of cooling posts, cooling rods, and cooling cones.

3. The liquid cooled cold plate of claim 2, further comprising:
cooling fins in thermal contact with the support base.

4. The liquid cooled cold plate of claim 1, wherein at least one of the liquid flow channels includes a liquid throttling zone.

5. The liquid cooled cold plate of claim 4, wherein at least one of the liquid flow channels includes a horizontal liquid throttling zone.

6. The liquid cooled cold plate of claim 1, further comprising:
vertical cooling fins coupled to a heat pipe in thermal contact with the support base.

7. The liquid cooled cold plate of claim 1, wherein the support base has a first thickness at the first region of cooling structures and a second thickness at the second region of cooling structures.

8. The liquid cooled cold plate of claim 1, wherein the first region of cooling structures comprises a plurality of interconnected cooling rods.

9. A liquid cooled cold plate for removing heat from an electronic apparatus, comprising:
a support base;
a first region of cooling structures in thermal contact with the support base for removing heat from a first heat flux region of the electronic apparatus;
at least one converging liquid flow channel that direct a cooling liquid to flow into the first region of cooling structures; and
at least one diverging liquid flow channel that direct a cooling liquid to flow out of the first region of cooling structures.

10. The liquid cooled cold plate of claim 9, wherein the first region of cooling structures comprises one of cooling posts, cooling rods, and cooling cones.

11. The liquid cooled cold plate of claim 9, further comprising:
cooling fins in thermal contact with the support base.

12. The liquid cooled cold plate of claim 9, further comprising:
a second region of cooling structures in thermal contact with the support base for removing heat from a second heat flux region of the electronic apparatus.

13. The liquid cooled cold plate of claim 12, wherein the support base has a first thickness at the first region of cooling structures and a second thickness at the second region of cooling structures.

14. The liquid cooled cold plate of claim 9, wherein the first region of cooling structures comprises a plurality if interconnected cooling rods.

15. A liquid cooled cold plate for removing heat from an electronic apparatus, comprising:
a support base;
a first region of cooling structures in thermal contact with the support base for removing heat from a first heat flux region of the electronic apparatus;
a second region of cooling structures in thermal contact with the support base for removing heat from a second heat flux region of the electronic apparatus;
a first liquid flow header for directing a cooling liquid to flow through the first region of cooling structures and the second region of cooling structures; and
a second liquid flow header for collecting the cooling liquid after it flows through the first region of cooling structures and the second region of cooling structures.

16. The liquid cooled cold plate of claim 15, wherein the first region of cooling structures comprises one of cooling posts, cooling rods, and cooling cones.

17. The liquid cooled cold plate of claim 15, wherein the first region of cooling structures comprises cooling fins in thermal contact with the support base.

18. The liquid cooled cold plate of claim 17, wherein a first cooling fin is thicker than a second cooling fin.

19. The liquid cooled cold plate of claim 15, wherein a first surface volume of the first region of cooling structures is greater than a second surface volume of the second region of cooling structures.

20. The liquid cooled cold plate of claim 15, wherein the first region of cooling structures comprises a plurality of interconnected cooling rods.
